(19) United States
(12) Patent Application Publication
(10) Pub. No.: US 2015/0319852 A1
(43) Pub. Date: Nov. 5, 2015

(54) PRINTED CIRCUIT BOARD, PRINTED CIRCUIT BOARD STRIP AND MANUFACTURING METHOD THEREOF

(71) Applicant: SAMSUNG ELECTRO-MECHANICS CO., LTD., Suwon (KR)

(72) Inventors: Tae Hong MIN, Suwon (KR); Yi Hyun JUNG, Suwon (KR); Suk Hyeon CHO, Suwon (KR); Young Gwan KO, Suwon (KR)

(73) Assignee: SAMSUNG ELECTRO-MECHANICS CO., LTD., Suwon (KR)

(21) Appl. No.: 14/470,011

(22) Filed: Aug. 27, 2014

(30) Foreign Application Priority Data
May 2, 2014 (KR) 10-2014-0053230

(51) Int. Cl. H05K 1/03; H05K 1/02; H05K 3/00; H05K 1/14; H05K 3/42; C03C 15/02; H05K 1/11

(52) U.S. Cl. CPC H05K 1/0306; C03C 15/02; H05K 1/0298; H05K 1/115; H05K 1/142; H05K 3/42; H05K 3/0044; H05K 2201/09136; H05K 2201/09154

(57) ABSTRACT

A printed circuit board and a manufacturing method thereof. According to one embodiment, a printed circuit board may include a core part; and a conductor pattern disposed on at least one surface of the core part, the core part includes a glass core having a side portion that is polished or thinner than a central portion of the core. According to another embodiment, a method of manufacturing the printed circuit board may include cutting a glass plate to form a glass core; and removing cracks from at least one side surface of the cut glass core.

### CROSS-REFERENCE TO RELATED APPLICATIONS

This application claims the foreign priority benefit of Korean Patent Application No. 10-2014-0053230 filed on May 2, 2014, with the Korean Intellectual Property Office, the disclosure of which is incorporated herein by reference.

### BACKGROUND

1. Field

The present disclosure relates to a printed circuit board, a printed circuit board strip and a manufacturing method thereof.

2. Description of Related Art

As printed circuit boards gradually become thinner, deformation of the board, such as warpage, twisting, and the like, during manufacturing have increased. In order to prevent the above-mentioned deformation, a glass core structure in which a glass plate is embedded in a core part of the printed circuit board has been suggested.

### SUMMARY

An exemplary embodiment in the present disclosure may provide a printed circuit board in which the occurrence of warpage is prevented through the use of a glass core, while a decrease in strength due to the occurrence of cracks in the glass core is also prevented, a printed circuit board strip and a manufacturing method thereof.

In order to accomplish the above-mentioned object, in an exemplary embodiment of the present disclosure, cracks occurring in a side portion of a glass core at the time of cutting a glass plate may be polished and removed.

Additional aspects and/or advantages will be set forth in part in the description which follows and, in part, will be apparent from the description, or may be learned by practice of the invention.

### BRIEF DESCRIPTION OF THE DRAWINGS

The above and other aspects, features and advantages of the present disclosure will be more clearly understood from the following detailed description taken in conjunction with the accompanying drawings, in which:

FIG. 1 is a cross-sectional view illustrating a structure of a printed circuit board according to an exemplary embodiment of the present disclosure;

FIG. 2 is an enlarged cross-sectional view of a core part of the printed circuit board according to the exemplary embodiment of the present disclosure;

FIG. 3 is a cross-sectional view of a glass core of the printed circuit board according to the exemplary embodiment of the present disclosure;

FIG. 4 is a perspective view of the glass core of the printed circuit board according to the exemplary embodiment of the present disclosure;

FIG. 5 is a cross-sectional view of a glass core of a printed circuit board according to another exemplary embodiment of the present disclosure;

FIG. 6 is a cross-sectional view of a glass core of a printed circuit board according to another exemplary embodiment of the present disclosure;

FIG. 7 is a perspective view of the glass core of the printed circuit board according to the exemplary embodiment of the present disclosure;

FIG. 8 is a perspective view of a printed circuit board strip according to an exemplary embodiment of the present disclosure;

FIG. 9 is a cross-sectional view taken along line A-A′ of FIG. 8;

FIG. 10 is a flowchart illustrating a method of manufacturing a printed circuit board according to an exemplary embodiment of the present disclosure;

FIG. 11 is a view illustrating a process of cutting a glass core according to an exemplary embodiment of the present disclosure;

FIG. 12 is a view illustrating a process of removing cracks from a glass core according to an exemplary embodiment of the present disclosure;

FIGS. 13A through 13D are views illustrating a process of removing cracks from a glass core according to another exemplary embodiment of the present disclosure;

FIG. 14 is a view illustrating a process of manufacturing a glass core having a central region to which a protective film is attached according to an exemplary embodiment of the present disclosure;

FIGS. 15A and 15B are views illustrating a process of forming a through-hole in an insulating material sheet so that a glass core may be embedded in the insulating material sheet according to an exemplary embodiment of the present disclosure;

FIGS. 16 through 17C are views illustrating a process of manufacturing a core part according to an exemplary embodiment of the present disclosure;

FIGS. 18A through 18G are views illustrating a method of manufacturing a printed circuit board strip according to an exemplary embodiment of the present disclosure; and

FIGS. 19A and 19B are views illustrating a unit cutting process of a printed circuit board strip according to an exemplary embodiment of the present disclosure.

### DESCRIPTION OF EMBODIMENTS

Hereinafter, embodiments of the present disclosure will be described in detail with reference to the accompanying drawings.

The disclosure may, however, be embodied in many different forms and should not be construed as being limited to the embodiments set forth herein. Rather, these embodiments are provided so that this disclosure will be thorough and complete, and will fully convey the scope of the disclosure to those skilled in the art.

In the drawings, the shapes and dimensions of elements may be exaggerated for clarity, and the same reference numerals will be used throughout to designate the same or like elements.

### Printed Circuit Board

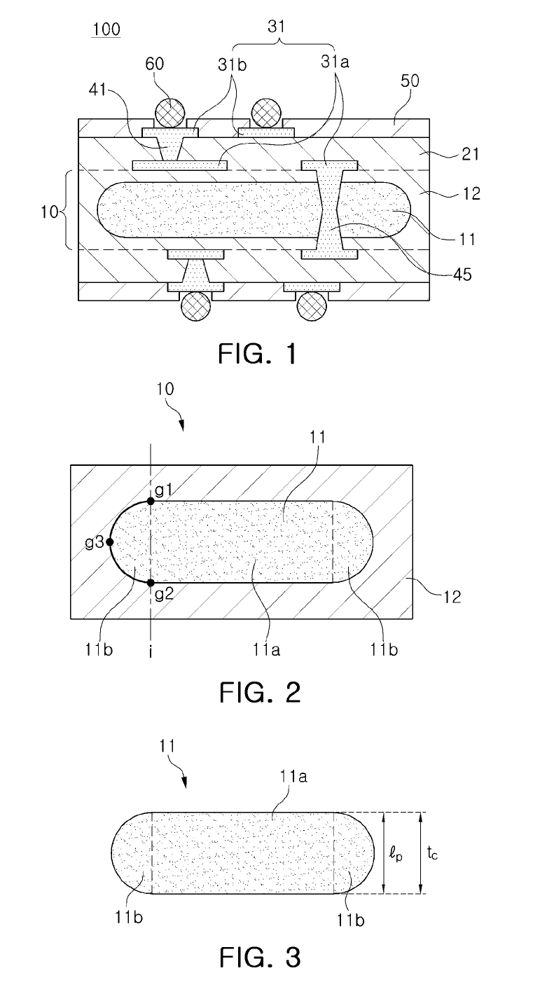

FIG. 1 is a cross-sectional view illustrating a structure of a printed circuit board according to an exemplary embodiment of the present disclosure.

Referring to FIG. 1, a printed circuit board 100 according to an exemplary embodiment of the present disclosure may include a core part 10 including a glass core 11 and an insulating material 12 enclosing the glass core.

That is, the glass core 11 may be embedded in the insulating material 12, such that it is not exposed to the outside. The insulating material 12 may be formed of a thermosetting resin such as an epoxy resin, a thermoplastic resin such as a polyimide resin, or a resin having a reinforcing material such as a glass fiber or an inorganic filler impregnated in the thermosetting resin or the thermoplastic resin, for example, prepreg.

Conductor patterns 31 and an insulating layer 21 may be disposed on one surface of the core part 10.

The insulating layer 21 may be formed of a thermosetting resin such as an epoxy resin, a thermoplastic resin such as a polyimide resin, or a resin having a reinforcing material such as a glass fiber or an inorganic filler impregnated in the thermosetting resin or the thermoplastic resin, for example, prepreg.

First and second conductor patterns 31a and 31b may be connected to each other through a via 41 penetrating through the insulating layer 21.

Here, although a build-up layer is illustrated in FIG. 1, the present disclosure is not limited thereto. That is, two or more build-up layers may be disposed on one surface of the core part 10.

The conductor pattern 31a and the insulating layer 21 may also be disposed on the other surface of the core part 10 opposing one surface thereof.

The first conductor patterns 31a disposed on both surfaces of the core part 10, respectively, may be connected to each other using a via 45 penetrating through the glass core 11.

A solder resist 50 may be formed on a surface of the printed circuit board 100, while allowing the outermost conductor pattern portion for an external terminal connection pad among the second conductor patterns 31b to be exposed. A solder bump 60 employable for mounting a semiconductor chip (not shown) may be disposed on the exposed conductor pattern for an external terminal connection pad.

The glass core 11 may contain glass, which is an amorphous solid.

A glass material that may be used in the exemplary embodiment of the present disclosure may include, for example, pure silicon diode (SiO₂ of about 100%), soda lime glass, boro-silicate glass, alumino-silicate glass, or the like. However, the glass material is not limited to the above-mentioned silicon-based glass compositions. That is, an alternative glass material, for example, fluoride glass, phosphate glass, chalcogenide glass, or the like, may be used.

In addition, the glass core may further contain other additives in order to form types of glass having specific physical properties. These additives may include magnesium, calcium, manganese, aluminum, lead, boron, iron, chromium, potassium, sulfur, and antimony, and a carbonate and/or an oxide containing these elements and/or other elements, as well as calcium carbonate (for example, lime) and sodium carbonate (for example, soda).

Here, the glass core containing the glass may prevent a warpage phenomenon occurring at the time of manufacturing the printed circuit board. However, cracks may occur during a cutting process, resulting in a decrease in strength.

Therefore, in the exemplary embodiment of the present disclosure, the glass core 11 having a protrusion portion formed on at least one side surface thereof through removing the cracks may improve the strength.

FIG. 2 is an enlarged cross-sectional view of the core part of the printed circuit board according to the exemplary embodiment of the present disclosure.

Referring to FIG. 2, the glass core 11 may include a central portion 11a and side portions 11b. The side portions 11b also define peripheral edges of the core.

The central portion 11 and the side portion 11b may be divided from each other based on a point (illustrated as a virtual line) at which a thickness of the glass core 11 starts to be decreased.

A central region of the glass core 11 having a uniform thickness may refer to the central portion 11a, and a region of the glass core 11 from the point at which the thickness of the glass core 11 starts to be decreased by polishing a glass material of an edge portion of the glass core 11 may refer to the side portion 11b. That is, a thickness of the side portion 11b of the glass core 11 may be less than that of the central portion 11a of the glass core 11.

In a cross-section of the core part 10 in a thickness direction, a central point g₃ in a boundary line between the side portion 11b of the glass core 11 and the insulating material 12 may deviate from a virtual vertical line i connecting the uppermost point g₁ and the lowermost point g₂ to each other.

The central point g₃ may be present in a region close to a side surface of the core part 10 in left and right regions divided by the virtual vertical line i.

The side portion 11b may have the form of a protrusion portion extended from the side surface of the central portion 11a.

That is, the glass core 11 according to the exemplary embodiment of the present disclosure may have a structure in which the protrusion portion 11b thinner than the central portion 11a is disposed on the side surface of the central portion 11a having a uniform thickness.

The protrusion portion 11b being extended and protruding from the side surface of the central portion 11a may be formed of the same glass material and may be integrated without a joint, or the like, between the central portion 11a and the protrusion portion 11b.

The protrusion portion 11b may be formed by polishing the side surface of the glass core.

Cracks may occur in each side surface, which is a cut surface, of the glass core 11 obtained by cutting a glass plate. The side surface of the glass core 11 in which the cracks have occurred may be polished to form the protrusion portion 11b, whereby the cracks may be removed. Therefore, the printed circuit board including the glass core 11 in which the protrusion portion 11b is formed on at least one side surface of the central portion 11a, may prevent a warpage phenomenon and significantly improved strength.

FIG. 3 is a cross-sectional view of the glass core of the printed circuit board according to the exemplary embodiment of the present disclosure.

As illustrated in FIG. 3, a cross section of the protrusion portion 11b in the thickness direction of the glass core may have a semi-ellipsoidal shape.

Here, a length lₚ of the protrusion portion 11b in contact with the central portion 11a in the thickness direction of the glass core may be equal to a thickness t_{c} of the central portion 11a.

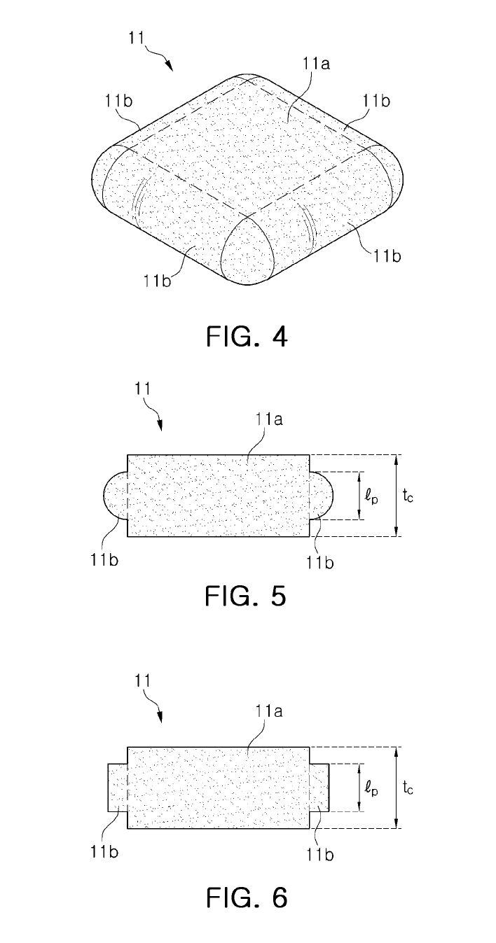

FIG. 4 is a perspective view of the glass core of the printed circuit board according to the exemplary embodiment of the present disclosure.

Referring to FIG. 4, the glass core 11 may include the central portion 11a and the protrusion portions 11b extended and protruding from the side surfaces of the central portion 11a.

As illustrated in FIG. 4, the protrusion portions 11b may be disposed on four side surfaces of the central portion 11a, respectively. Since cracks may occur in all four side surfaces of the glass core 11, cut surfaces, the protrusion portions 11b may be formed on the four side surfaces of the glass core, respectively, by polishing all of the four side surfaces.

A cross section of the protrusion portion 11b in the thickness direction of the glass core 11 may have a semi-ellipsoidal shape as illustrated in FIG. 4.

FIG. 5 is a cross-sectional view of a glass core of a printed circuit board according to another exemplary embodiment of the present disclosure.

Referring to FIG. 5, a cross section of a protrusion portion 11b in a thickness direction of a glass core 11 according to another exemplary embodiment of the present disclosure may have a semi-ellipsoidal shape as illustrated in FIG. 3.

However, in this exemplary embodiment of the present disclosure illustrated in FIG. 5, a length lₚ of the protrusion portion 11b in contact with a central portion 11a in the thickness direction of the glass core 11 may be less than a thickness tₚ of the central portion 11a.

As the length lₚ of the protrusion portion 11b in contact with the central portion 11a in the thickness direction of the glass core is reduced to be less than the thickness tₚ of the central portion 11a, a polishing degree is increased. In the case of chemically polishing the glass core 11 by immersing the glass core 11 in a polishing solution, as a time for which the glass core 11 is immersed in the polishing solution is increased, the length lₚ of the protrusion portion 11b in contact with the central portion 11a in the thickness direction of the glass core is reduced to be less than the thickness t_{c} of the central portion 11a.

FIG. 6 is a cross-sectional view of a glass core of a printed circuit board according to another exemplary embodiment of the present disclosure.

Referring to FIG. 6, a cross section of a protrusion portion 11b in a thickness direction of a glass core 11 according to this exemplary embodiment of the present disclosure may have a rectangular shape.

Here, a length lₚ of the protrusion portion 11b in contact with a central portion 11a in the thickness direction of the glass core may be less than a thickness t_{c} of the central portion 11a.

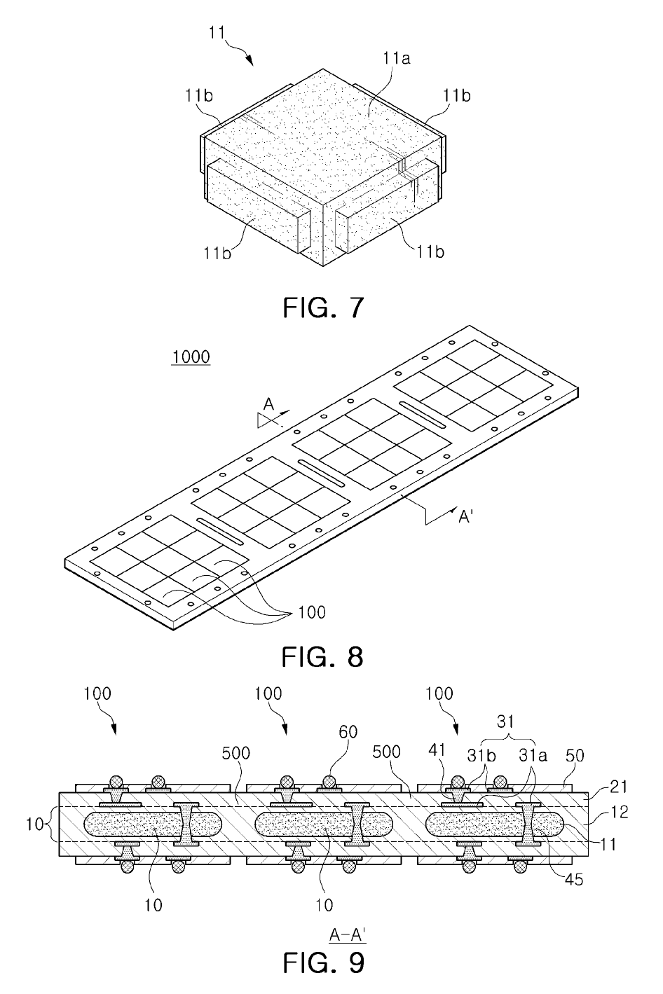

FIG. 7 is a perspective view of the glass core of the printed circuit board according to the exemplary embodiment of the present disclosure illustrated in FIG. 6.

Referring to FIG. 7, the glass core 11 may include the central portion 11a and the protrusion portions 11b extended and protruding from side surfaces of the central portion 11a.

A cross section of the protrusion portion 11b in the thickness direction of the glass core 11 may have a rectangular shape as illustrated in FIG. 7, and the length lₚ of the protrusion portion 11b in contact with the central portion 11a in the thickness direction of the glass core may be less than the thickness t_{c} of the central portion 11a.

### Printed Circuit Board Strip

FIG. 8 is a perspective view of a printed circuit board strip according to an exemplary embodiment of the present disclosure.

Referring to FIG. 8, a printed circuit board strip 1000 according to an exemplary embodiment of the present disclosure may include a plurality of printed circuit boards 100.

A semiconductor chip (not shown) may be mounted on one surface of the printed circuit board 100 and a main board (not shown) may be connected to the other surface thereof.

An array and a structure of the printed circuit boards 100 disposed in the printed circuit board strip 1000 are not limited to those illustrated in FIG. 8, but may be modified depending on the intention of a designer.

FIG. 9 is a cross-sectional view taken along line A-A′ of FIG. 8.

Referring to FIG. 9, each of the printed circuit boards 100 in the printed circuit board strip 1000 may include a core part 10 including a glass core 11 and an insulating material 12 enclosing the glass core 11.

That is, the glass cores 11, cut to have a size smaller than that of the printed circuit board 100, may be disposed in the printed circuit boards 100, respectively.

Since the glass cores 11 smaller than the printed circuit boards 100 are embedded in the printed circuit boards 100, when the printed circuit board strip 1000 is cut into the individual printed circuit boards 100, the glass cores 11 may be not cut or exposed. Thus, the occurrence of cracks or separation of the glass core 11 from the insulating layer 21 may be prevented.

However, cracks have already occurred in the glass cores at the time of cutting a glass plate into the glass cores, resulting in a decrease in strength.

Therefore, in this exemplary embodiment of the present disclosure, the glass core 11 may be formed to have the protrusion portion on at least one side surface thereof through an operation of removing the cracks, thereby achieving improved strength.

In a cross section of the core part 10 in a thickness direction, a central point g₃ in a boundary line between the side portion 11b of the glass core 11 and the insulating material 12 may deviate from a virtual vertical line i connecting the uppermost point g₁ and the lowermost point g₂ to each other.

The side portion 11b of the glass core 11 may have the form of the protrusion portion extended from the side surface of the central portion 11a.

That is, the glass core 11 according to the exemplary embodiment of the present disclosure may have a structure in which the protrusion portion 11b thinner than the central portion 11a is disposed on the side surface of the central portion 11a having a uniform thickness.

The protrusion portion 11b may be formed by polishing the side surface of the glass core 11.

Cracks may occur in side surfaces, cut surfaces, of the glass core 11. The side surfaces of the glass core 11 in which the cracks have occurred may be polished to form the protrusion portions 11b, whereby the cracks may be removed.

Therefore, the printed circuit board strip 1000, in which each of the printed circuit boards 100 includes the glass core 11 having the protrusion portion 11b disposed on at least one side surface of the central portion 11a, may prevent a warpage phenomenon and significantly improved strength.

In the exemplary embodiment of the present disclosure, a cross section of the protrusion portion 11b in the thickness direction of the glass core 11 may have a semi-ellipsoidal shape.

Here, a length lₚ of the protrusion portion 11b in contact with the central portion 11a in the thickness direction of the glass core may be equal to a thickness t_{c} of the central portion 11a.

In another exemplary embodiment of the present disclosure, a cross section of a protrusion portion 11b in the thickness direction of a glass core 11 may have a semi-ellipsoidal shape, and a length lₚ of the protrusion portion 11b in contact with a central portion 11a in the thickness direction of the glass core may be less than a thickness t_{c} of the central portion 11a.

As the length lₚ of the protrusion portion 11b in contact with the central portion 11a in the thickness direction of the glass core is reduced to be less than the thickness t_{c} of the central portion 11a, a polishing degree is increased. In the case of chemically polishing the glass core 11 by immersing the glass core 11 in a polishing solution, as a time for which the glass core 11 is immersed in the polishing solution is increased, the length lₚ of the protrusion portion 11b in contact with the central portion 11a in the thickness direction of the glass core is reduced to be less than the thickness t_{c} of the central portion 11a.

In another exemplary embodiment of the present disclosure, a cross section of a protrusion portion 11b in the thickness direction of a glass core 11 may have a rectangular shape.

Here, a length lₚ of the protrusion portion 11b in contact with a central portion 11a in the thickness direction of the glass core may be less than a thickness t_{c} of the central portion 11a.

The protrusion portions 11b may be disposed on four side surfaces of the central portion 11a, respectively. Since cracks may occur in all of the four side surfaces of the glass core 11, the protrusion portions 11b may be formed on the four side surfaces of the glass core 11, respectively, by polishing all of the four side surfaces.

### Method of Manufacturing Printed Circuit Board

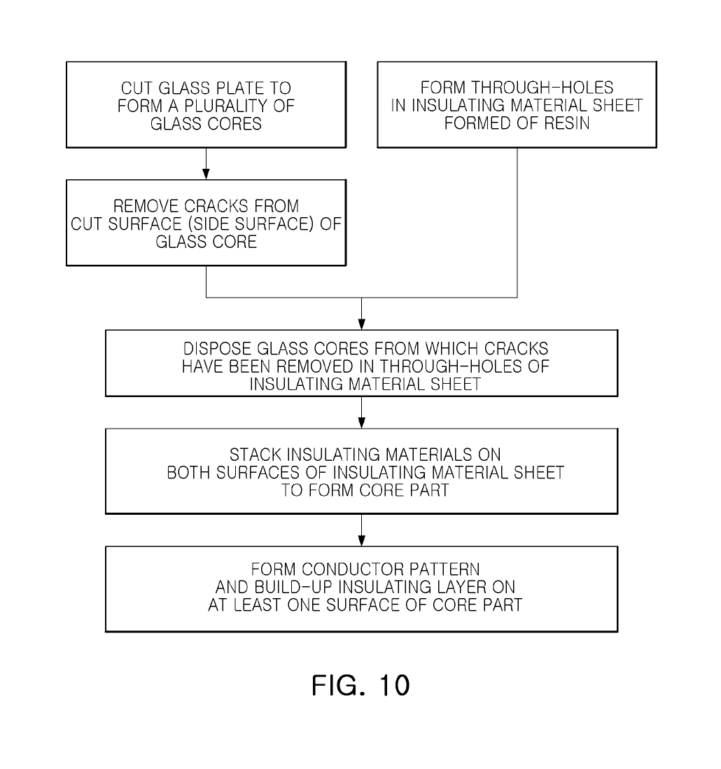

FIG. 10 is a flowchart illustrating a method of manufacturing a printed circuit board according to an exemplary embodiment of the present disclosure.

Referring to FIG. 10, a glass plate may first be cut to form a plurality of glass cores.

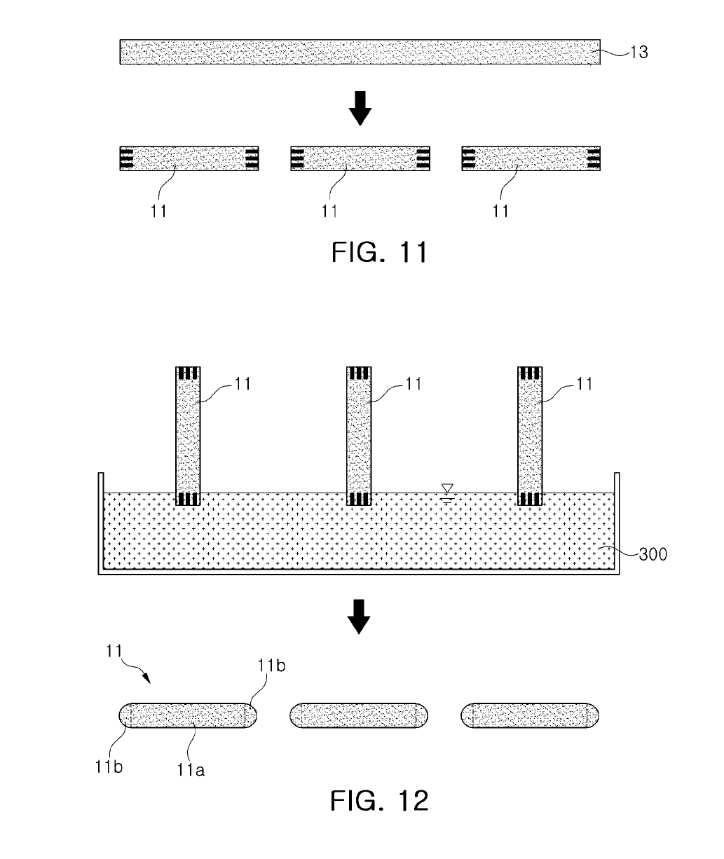

Referring to FIG. 11, the glass plate 13 may be cut to form the plurality of glass cores 11.

The glass plate 13 may be cut using a laser, without being limited thereto. That is, several cutting processes may be used in consideration of characteristics of a glass material.

In cutting the glass plate 13 in order to manufacture the glass core 11 as described above, cracks may occur in a cut surface of the manufactured glass core 11. When the glass core 11 in which cracks have occurred is inserted into a printed circuit board, strength of the printed circuit board that is finally produced may be decreased.

Therefore, in the exemplary embodiment of the present disclosure, a process of removing cracks in the cut glass core 11 may be performed.

At least one side surface of the cut glass core 11 may be polished to remove the cracks, and thus, the protrusion portion 11b may be formed on the side surface of the polished glass core 11.

The cracks having occurred at the time of cutting the glass plate may be removed by polishing the cut glass core 11. By inserting the glass core 11 including the protrusion portion, from which the cracks have been removed, into the printed circuit board, the strength of the printed circuit board may be improved.

FIG. 12 is a view illustrating a process of removing cracks from a glass core and forming a protrusion portion according to an exemplary embodiment of the present disclosure.

Referring to FIG. 12, a side surface of the glass core 11 may be immersed in a polishing solution 300 to form the protrusion portion 11b.

Cracks may be removed by a chemical polishing process of immersing the side surface of the glass core 11 having the cracks in the polishing solution 300, and the protrusion portion 11b may be formed on one side surface of the non-polished central portion 11a of the glass core 11.

The polishing solution 300 may be an acid solution. For example, an acid solution including fluorine (F) may be used. However, the polishing solution 300 is not limited thereto, and any polishing solution capable of chemically polishing the glass core 11 may be used.

Since cracks may occur in all of four side surfaces of the glass core 11, which are cut surfaces, each of the four side surfaces of the glass core 11 may be immersed in the polishing solution 300 to thereby be polished.

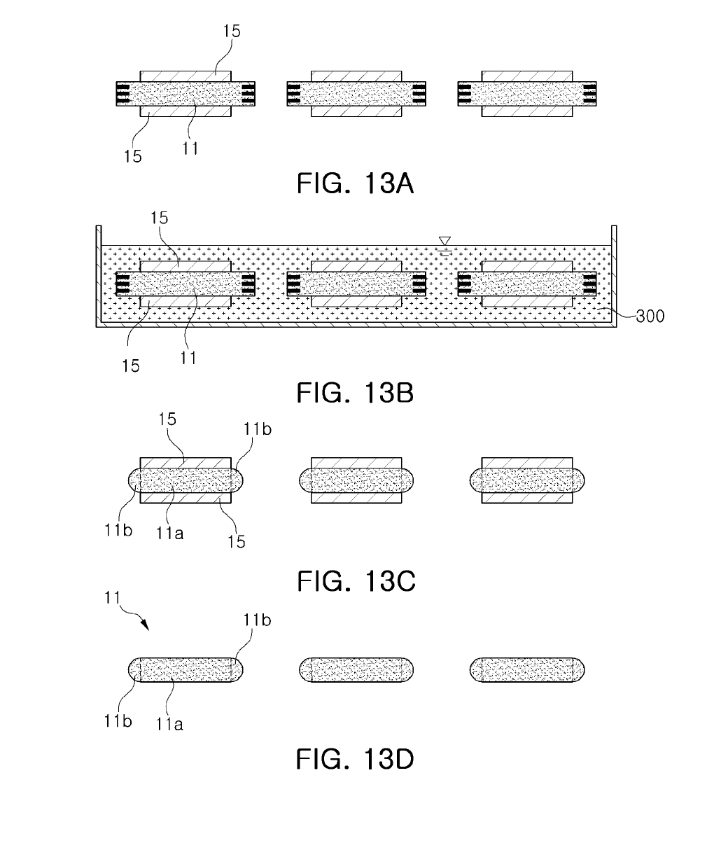

FIGS. 13A through 13D are views illustrating a process of removing cracks from a glass core and forming a protrusion portion according to another exemplary embodiment of the present disclosure.

Referring to FIG. 13A, protective films 15 may be prepared to be attached to central regions of upper and lower surfaces of a glass core 11.

Cracks may occur in side surfaces of the glass core 11, which are cut surfaces. The protective films 15 may be attached to the central regions of the upper and lower surfaces of the glass core 11 having no cracks, except for regions of the upper and lower surfaces of the glass core 11 in which cracks have occurred.

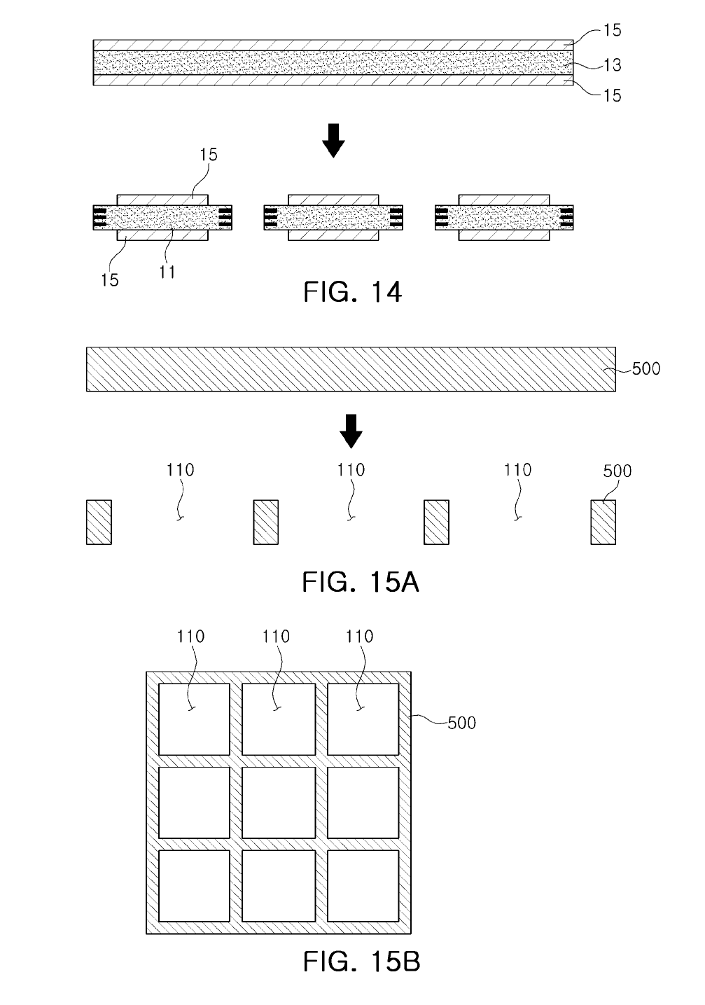

Meanwhile, a method of preparing the glass core 11 having the protective films 15 attached to the central regions of the upper and lower surfaces of the glass core 11 is not particularly limited. For example, the glass core 11 may be prepared using a method illustrated in FIG. 14.

Referring to FIG. 14, the protective films 15 may be attached to the upper and lower surfaces of the glass plate 13, respectively, and the glass plate 13 to which the protective films 15 are attached may be cut to form the glass cores 11.

Here, the glass plate 13 may be cut using a laser. Portions of the protective films 15 adjacent to a cut surface of the glass core may be removed at the time of cutting the glass plate 13 using the laser, such that the glass core 11 may be formed to have the protective films 15 in only the central regions of the upper and lower surfaces thereof.

Referring to FIG. 13B, the glass core 11 having the central regions of the upper and lower surfaces to which the protective films 15 are attached may be immersed in the polishing solution 300 to form the protrusion portions 11b.

The protective film 15 may contain a polymer that is not dissolved by the polishing solution 300 (for example, an acid solution). Therefore, when the glass core 11 having the protective films 15 is immersed in the polishing solution 300, the central regions of the glass core 11 to which the protective films 15 are attached may not be polished by the polishing solution 300, and only an exposed region of the glass core 11 to which the protective films 15 are not attached may be polished by the polishing solution 300.

When the glass core 11 to which the protective films 15 are attached is immersed in the polishing solution 300 to thereby be polished, four side surfaces of the glass core, which are cut surfaces, are simultaneously polished without being individually immersed in the polishing solution 300.

Referring to FIG. 13C, a central portion 11a of the glass core to which the protective films 15 are attached may not be polished by the polishing solution 300, and side portions of the glass core 11 to which the protective films 15 are not attached may be polished by the polishing solution 300 to thereby form the protrusion portions 11b.

Referring to FIG. 13D, the protective films 15 attached to the upper and lower surfaces of the glass core 11 may be removed.

The protective films 15 may contain a polymer that is not dissolved by the polishing solution 300 (for example, an acid solution), but is dissolved by an alkaline solution or a neutral solution. Therefore, the protective films 15 may be dissolved and removed using the alkaline solution or the neutral solution.

The glass core 11 manufactured according to the exemplary embodiment of the present disclosure may have the central portion 11a and the protrusion portion 11b disposed on the side surface of the central portion 11a.

In an exemplary embodiment of the present disclosure, a cross section of the protrusion portion 11b in the thickness direction of the glass core 11 may have a semi-ellipsoidal shape.

Here, a length lₚ of the protrusion portion 11b in contact with the central portion 11a in the thickness direction of the glass core may be equal to a thickness t_{c} of the central portion 11a.

In another exemplary embodiment of the present disclosure, a cross section of a protrusion portion 11b in the thickness direction of a glass core 11 may have a semi-ellipsoidal shape, and a length lₚ of the protrusion portion 11b in contact with a central portion 11a in the thickness direction of the glass core 11 may be less than a thickness t_{c} of the central portion 11a.

As the length lₚ of the protrusion portion 11b in contact with the central portion 11a in the thickness direction of the glass core is reduced to be less than the thickness t_{c} of the central portion 11a, a polishing degree is increased. In the case of chemically polishing the glass core 11 by immersing the glass core 11 in a polishing solution, as a time for which the glass core 11 is immersed in the polishing solution is increased, the length lₚ of the protrusion portion 11b in contact with the central portion 11a in the thickness direction of the glass core is reduced to be less than the thickness t_{c} of the central portion 11a.

In another exemplary embodiment of the present disclosure, a cross section of a protrusion portion 11b in the thickness direction of of a glass core 11 may have a rectangular shape.

Here, a length lₚ of the protrusion portion 11b in contact with a central portion 11a in the thickness direction of the glass core may be less than a thickness t_{c} of the central portion 11a.

Next, the glass core 11 having the protrusion portions 11b formed on the side surfaces of the central portion 11a may be embedded in an insulating material.

Referring to FIGS. 15A and 15B, an insulating material sheet 500 may be prepared, and through-holes 110 may be formed in the insulating material sheet 500. The insulating material sheet 500 may be formed of a thermosetting resin such as an epoxy resin, a thermoplastic resin such as a polyimide resin, or a resin having a reinforcing material such as a glass fiber or an inorganic filler impregnated in the thermosetting resin or the thermoplastic resin, for example, prepreg.

The through-holes may be formed using mechanical drilling or laser drilling, without being limited thereto.

Next, the glass cores 11 including the protrusion portions 11b from which the cracks have been removed may be disposed in the through-holes 110, respectively, to thereby form a core part.

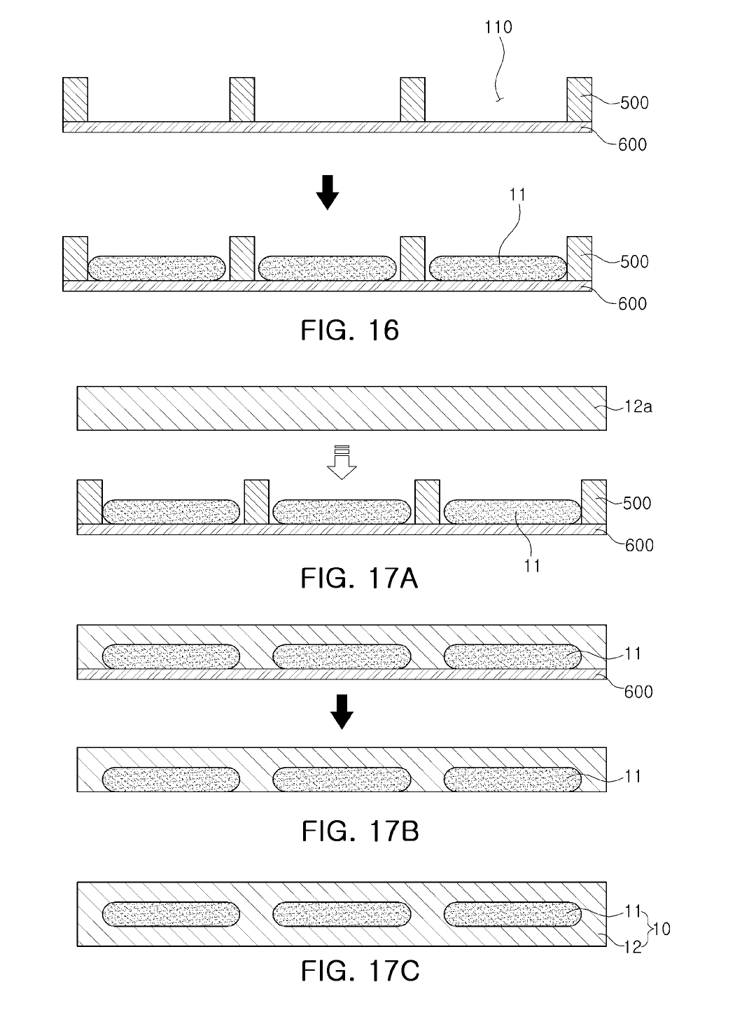

Referring to FIG. 16, an adhesive layer 600 may be attached to one surface of the insulating material sheet 500 in which the through-holes 110 are formed, and the glass cores 11 may be disposed in the through-holes 110, respectively. The glass cores 11 may be attached to the adhesive layer 600.

Referring to FIG. 17A, an insulating material sheet 12a may be stacked and compressed on the other surface of the insulating material sheet 500 opposing one surface of the insulating material sheet 500 to which the adhesive layer 600 is attached, by heating. In this case, the insulating material sheet 12a may partially flow in to fill the through-holes 110 so as to enclose the glass cores 11. The insulating material sheet 12a may be formed of a thermosetting resin such as an epoxy resin, a thermoplastic resin such as a polyimide resin, or a resin having a reinforcing material such as a glass fiber or an inorganic filler impregnated in the thermosetting resin or the thermoplastic resin, for example, prepreg.

Referring to FIG. 17B, after the insulating material sheet 12a is stacked and compressed, the adhesive layer 600 may be removed.

Referring to FIG. 17C, the insulating material sheet 12a may also be stacked and compressed on a surface from which the adhesive layer 600 have been removed, and thus, the core part 10 may be formed to include the glass core 11 and the insulating material 12 enclosing the glass core 11.

Next, the conductor patterns 31a and 31b and the insulating layer 21 may be formed on at least one surface of the core part 10.

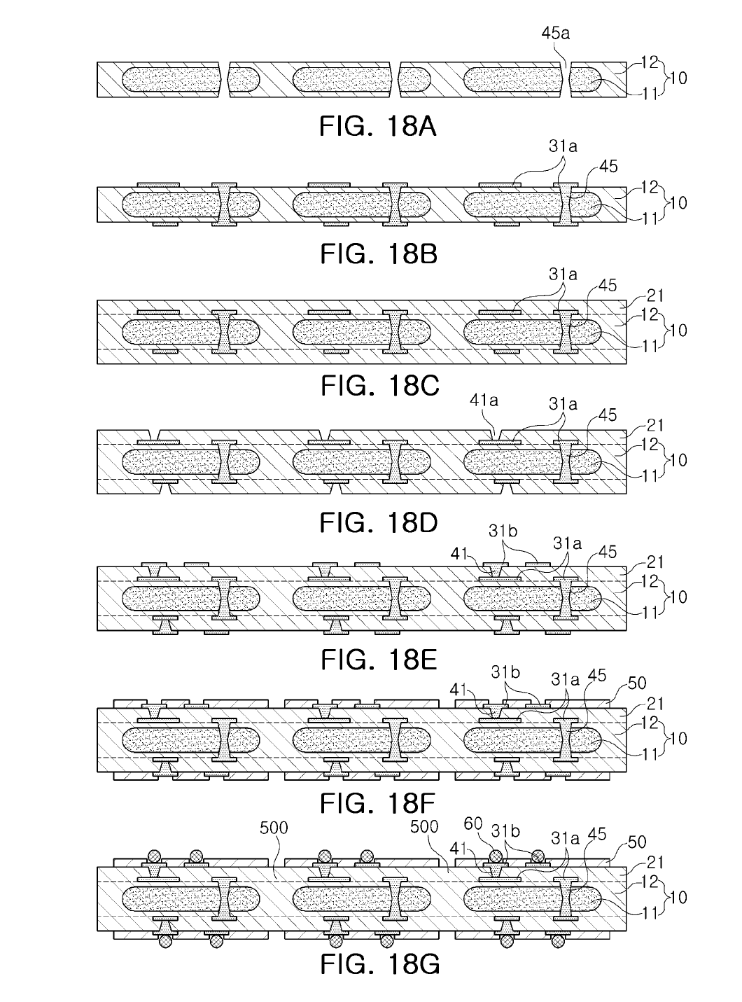

FIGS. 18A through 18G are views illustrating a method of manufacturing a printed circuit board strip according to an exemplary embodiment of the present disclosure.

Referring to FIG. 18A, via holes 45a penetrating through the glass core 11 may be formed in the core part 10.

The via holes 45a may be formed using mechanical drilling, laser drilling, sand blasting, or the like, without being limited thereto.

Referring to FIG. 18B, the via holes 45a may be filled with a conductive metal to form the vias 45, and the first conductor patterns 31a may be formed on the core part 10 to be electrically connected to each other by the vias 45.

The filling of the conductive metal and the forming of the first conductor patterns 31a may be performed using a plating process, or the like. Here, the conductive metal may be any metal having excellent electrical conductivity, for example, copper (Cu).

Referring to FIG. 18C, the insulating layer 21 may be stacked on the first conductor patterns 31a. The insulating layer 21 may be formed of a thermosetting resin such as an epoxy resin, a thermoplastic resin such as a polyimide resin, or a resin having a reinforcing material such as a glass fiber or an inorganic filler impregnated in the thermosetting resin or the thermoplastic resin, for example, prepreg.

Referring to FIG. 18D, via holes 41a may be formed to penetrate through the insulating layer 21.

The via holes 41a may be formed using mechanical drilling, laser drilling, sand blasting, or the like, without being limited thereto.

Referring to FIG. 18E, the via holes 41a may be filled with a conductive metal to form the vias 41, and the second conductor patterns 31b may be formed on the insulating layer 21 to be electrically connected to the first conductor patterns 31a by the vias 41.

The filling of the conductive metal and the forming of the second conductor patterns 31b may be performed using a plating process, or the like, and the conductive metal may be any metal having excellent electrical conductivity, for example, copper (Cu).

The process of forming the vias 41 and the second conductor patterns 31b may be repeated to form two or more build-up layers (not shown) on one surface of the core part 10.

Referring to FIG. 18F, a solder resist 50 may be formed on a surface of the printed circuit board strip 1000 while allowing the outermost conductor pattern portion for an external terminal connection pad among the second conductor patterns 31b to be exposed.

Referring to FIG. 18G, a solder bump 60 employable for mounting a surface mounting component (not shown) may be disposed on the exposed conductor pattern for an external terminal connection pad.

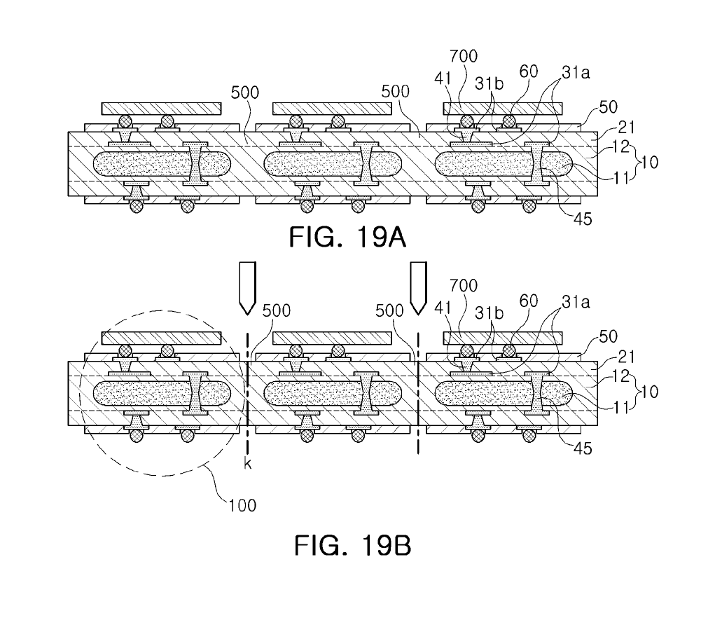

FIGS. 19A and 19B are views illustrating a unit cutting process of the printed circuit board strip according to an exemplary embodiment of the present disclosure.

Referring to FIG. 19A, a surface mounting component 700 may be mounted on the solder bump 60. The surface mounting component 700, a component electrically connected to the printed circuit board and is in charge of a predetermined function, may be, for example, an integrated circuit (IC) chip.

Referring to FIG. 19B, the manufactured printed circuit board strip 1000 may be cut along a cut line k to form individual printed circuit boards 100.

Here, since the glass cores 11 are disposed in the printed circuit boards 100, respectively, and are enclosed by the insulating material 12, when the printed circuit board strip 1000 according to this exemplary embodiment of the present disclosure is cut in the unit cutting process, the glass cores 11 may not be cut or exposed, and thus, the occurrence of cracks or separation of the glass core 11 from the insulating layer 21 may be prevented.

As set forth above, according to exemplary embodiments of the present disclosure, occurrence of warpage in the printed circuit board may be prevented by using the glass core, while cracks occurring at the time of cutting the glass core is removed, whereby the strength of the printed circuit board may be improved.

While exemplary embodiments have been shown and described above, it will be apparent to those skilled in the art that modifications and variations could be made without departing from the spirit and scope of the present disclosure as defined by the appended claims.

What is claimed is:

1. A printed circuit board, comprising:
a core part that includes a glass core of which a side portion is polished; and
a conductor pattern disposed on at least one surface of the core part.

2. The printed circuit board of claim 1, wherein the side portion of the glass core is thinner than a central portion thereof.

3. The printed circuit board of claim 2, wherein
the core part further includes an insulating material in which the glass core is embedded, and
the conductor pattern is disposed on a surface of the insulating material.

4. The printed circuit board of claim 3, wherein in a cross section of the core part taken in a thickness direction of the core part, a central point in a boundary line between the side portion of the glass core and the insulating material deviates from a virtual vertical line connecting an uppermost point and a lowermost point to each other.

5. The printed circuit board of claim 4, wherein a cross section of the side portion in a thickness direction of the glass core has a semi-ellipsoidal shape.

6. The printed circuit board of claim 5, wherein a length of the side portion in contact with the central portion in the thickness direction of the glass core is equal to a thickness of the central portion.

7. The printed circuit board of claim 5, wherein a length of the side portion in contact with the central portion in the thickness direction of the glass core is less than a thickness of the central portion.

8. The printed circuit board of claim 4, wherein a cross section of the side portion in a thickness direction of the glass core has a rectangular shape, and
a length of the side portion in contact with the central portion in the thickness direction of the glass core is less than a thickness of the central portion.

9. A printed circuit board, comprising:
a core part including a glass core and an insulating material enclosing the glass core, the glass core including a central portion and a protrusion portion extended from at least one side surface of the central portion, the protrusion portion being thinner than the central portion; and
a conductor pattern disposed on at least one surface of the core part.

10. The printed circuit board of claim 9, wherein a cross section of the protrusion portion in a thickness direction of the glass core has a semi-ellipsoidal shape.

11. The printed circuit board of claim 10, wherein a length of the protrusion portion in contact with the central portion in the thickness direction of the glass core is equal to a thickness of the central portion.

12. The printed circuit board of claim 10, wherein a length of the protrusion portion in contact with the central portion in the thickness direction of the glass core is less than a thickness of the central portion.

13. The printed circuit board of claim 9, wherein a cross section of the protrusion portion in a thickness direction of the glass core has a rectangular shape, and
a length of the protrusion portion in contact with the central portion in the thickness direction of the glass core is less than a thickness of the central portion.

14. The printed circuit board of claim 9, wherein the protrusion is disposed on four side surfaces of the central portion.

15. A printed circuit board strip comprising a plurality of printed circuit boards of claim 1.

16. A method of manufacturing a printed circuit board including a core part and a conductor pattern disposed on at least one surface of the core part, the method comprising:
cutting a glass plate to form a glass core; and
removing cracks from at least one side surface of the cut glass core.

17. The method of claim 16, wherein the cracks are removed by polishing the side surface of the glass core.

18. The method of claim 17, wherein the side surface of the glass core is immersed in a polishing solution.

19. The method of claim 17, wherein the glass core is immersed in a polishing solution after a protective film is attached to central regions of upper and lower surfaces of the glass core.

20. The method of claim 19, wherein the protective film is not dissolved by the polishing solution.

21. The method of claim 16, further comprising:
forming a through-hole in an insulating material sheet;
disposing the glass core in the through-hole; and
stacking an insulating material on at least one surface of the glass core.

22. The method of claim 21, wherein the through-hole is filled with the insulating material stacked on the surface of the glass core.

23. The method of claim 21, further comprising forming the conductor pattern on a surface of the insulating material stacked on the surface of the glass core

24. A printed circuit board, comprising:
a glass core having at least one side portion that is thinner than a central portion of the core;
an insulating part, formed on a lateral surface of the side portion and also on upper and lower surfaces of the glass core; and
a conductor pattern disposed the insulating part.

25. The printed circuit board of claim 24, wherein the conductor pattern is a first conductor pattern disposed on a first surface of the insulating part, and the printed circuit board further comprises:
a second conductor pattern disposed on a second surface of the insulating part;
a via passing through the glass core, the via being between and electrically connecting the first and second conductor patterns; and
a build-up insulating layer formed on the insulating part and covering a portion of the first conductor pattern.

26. A printed circuit board strip comprising a plurality of printed circuit boards of claim 24,
wherein the insulating parts of the printed circuit boards are each a respective portion of a single insulating layer, the single insulating layer being present between the respective glass cores of the printed circuit board and laterally adjoining the printed circuit boards to each other.

27. A method of manufacturing the printed circuit board of claim 24, comprising:
preparing a plurality of the glass cores, each cut from a glass plate and each having at least one side portion that is thinner than a central portion of the respective core;
forming a plurality of through-holes in an insulating material sheet;
disposing each of the glass cores in a respective through hole and then filling the through holes with an insulating material to form a printed circuit board strip; and
cutting the printed circuit board strip at dicing lines passing between proximate glass cores to form a printed circuit board having been separated from the rest of the printed circuit board strip.
